(19) United States
(12) Patent Application Publication
(10) Pub. No.: US 2026/0075971 A1
(43) Pub. Date: Mar. 12, 2026

(54) IMAGE SENSOR

(71) Applicant: SAMSUNG ELECTRONICS CO., LTD., Suwon-si (KR)

(72) Inventors: Wonhyeok Kim, Suwon-si (KR); Uisik Kim, Suwon-si (KR); Iljoong Kim, Suwon-si (KR)

(21) Appl. No.: 19/174,674

(22) Filed: Apr. 9, 2025

(30) Foreign Application Priority Data
Sep. 10, 2024 (KR) 10-2024-0123169

(51) Int. Cl. H10F 39/00; H10F 39/18

(52) U.S. Cl. CPC H10F 39/805; H10F 39/014; H10F 39/024; H10F 39/182; H10F 39/8053; H10F 39/8063; H10F 39/807

(57) ABSTRACT

An image sensor may include a substrate having a first surface and a second surface, which are opposite to each other, and including a plurality of photoelectric conversion parts, a first isolation structure disposed in the substrate to separate the photoelectric conversion parts from each other, an oxide structure on the first isolation structure, and a micro lens on the oxide structure. The first isolation structure and the micro lens may be vertically overlapped with each other, and the first isolation structure may include a first isolation conductive pattern. The oxide structure may be in contact with the first isolation conductive pattern, and a bottom surface of the oxide structure may be placed between the first and second surfaces of the substrate.

### CROSS-REFERENCE TO RELATED APPLICATION

This U.S. patent application claims priority under 35 U.S. C. § 119 to Korean Patent Application No. 10-2024-0123169, filed on Sep. 10, 2024, in the Korean Intellectual Property Office, the entire contents of which are hereby incorporated by reference.

### BACKGROUND

The present disclosure relates to image sensors, and in particular, to image sensors with improved electrical and optical characteristics.

An image sensor is a semiconductor device converting an optical image to electric signals. The image sensor is classified into two types: a charge coupled device (CCD) type and a complementary metal-oxide-semiconductor (CMOS) type. In general, the CMOS-type image sensor may be called “CIS”. The CIS includes a plurality of pixels that are two-dimensionally arranged. Each of the pixels may include a photodiode (PD). The photodiode is used to convert an incident light to an electric signal.

### SUMMARY

Some aspects of the present disclosure provide image sensors with reduced optical loss and improved sensitivity.

According to some implementations of the present disclosure, an image sensor may include a substrate having a first surface and a second surface, which are opposite to each other, and including a plurality of photoelectric conversion parts, a first isolation structure disposed in the substrate to separate the photoelectric conversion parts from each other, an oxide structure on the first isolation structure, and a micro lens on the oxide structure. The first isolation structure and the micro lens may be vertically overlapped with each other, and the first isolation structure may include a first isolation conductive pattern. The oxide structure may be in contact with the first isolation conductive pattern, and a bottom surface of the oxide structure may be placed between the first and second surfaces of the substrate.

According to some implementations, an image sensor may include a substrate having a first surface and a second surface, which are opposite to each other, and including a plurality of photoelectric conversion parts, a first isolation structure and a second isolation structure provided in the substrate and spaced apart from each other in a first direction, an oxide structure on the first isolation structure, and a micro lens on the oxide structure. The first isolation structure may be vertically overlapped with the micro lens, and the first isolation structure may include a first isolation conductive pattern. The oxide structure may include a first portion and a second portion on the first portion, and the first portion may be in contact with the first isolation conductive pattern. The second portion may be extended, on the second surface, and a height of the first portion may be larger than a height of the second portion.

According to some implementations, an image sensor may include a substrate including a first pixel group and a second pixel group, which are adjacent to each other, each of the first and second pixel groups including a plurality of photoelectric conversion parts, a first isolation structure disposed in the substrate to separate the first and second pixel groups from each other, a second isolation structure disposed in the substrate to separate the photoelectric conversion parts, which are included in each of the first and second pixel groups, from each other, and an oxide structure on the second isolation structure. The first and second isolation structures may include a first isolation conductive pattern and a second isolation conductive pattern, respectively. A height of the second isolation conductive pattern may be smaller than a height of the first isolation conductive pattern. The oxide structure may include a first portion and a second portion protruding from the first portion. The first portion may be in contact with the first isolation conductive pattern, and the second portion may be in contact with the second isolation conductive pattern. A height of the second portion may range from 0.5 μm to 1.5 μm.

### BRIEF DESCRIPTION OF THE DRAWINGS

FIG. 1 is a plan view illustrating an example of a image sensor.

FIG. 2 is a sectional view taken along a line A-A′ of FIG. 1.

FIG. 3 is a sectional view taken along a line B-B′ of FIG. 2.

FIG. 4 is an enlarged sectional view illustrating a portion ‘CU1’ of FIG. 2.

FIG. 5 is a sectional view taken along the line A-A′ of FIG. 1.

FIG. 6 is an enlarged sectional view illustrating a portion ‘CU2’ of FIG. 5.

FIGS. 7, 8, 9, and 10 are sectional views illustrating an example of a process of fabricating an image sensor.

FIG. 11 is a plan view illustrating an example of an image sensor.

### DETAILED DESCRIPTION

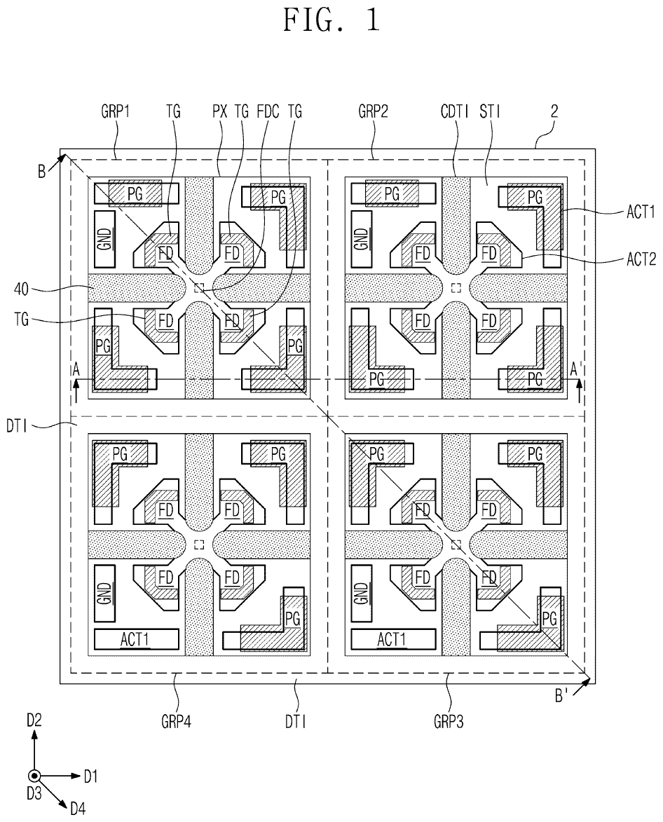

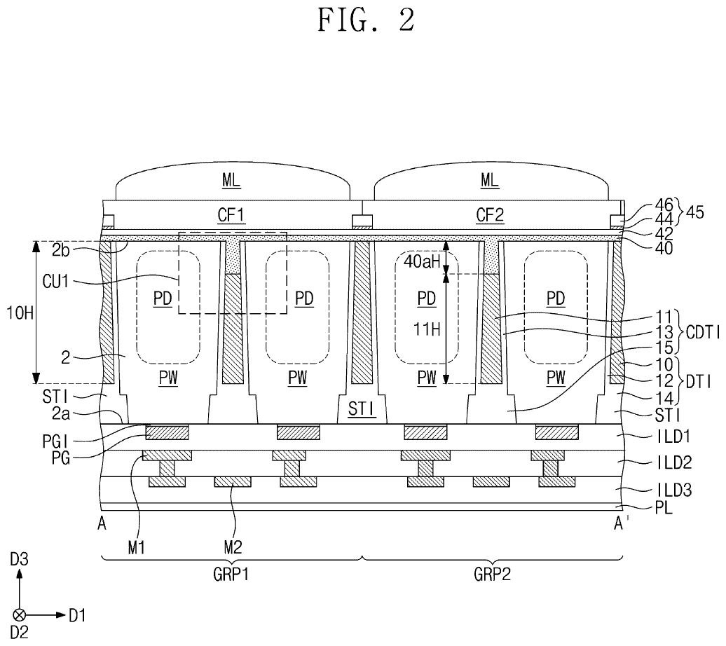

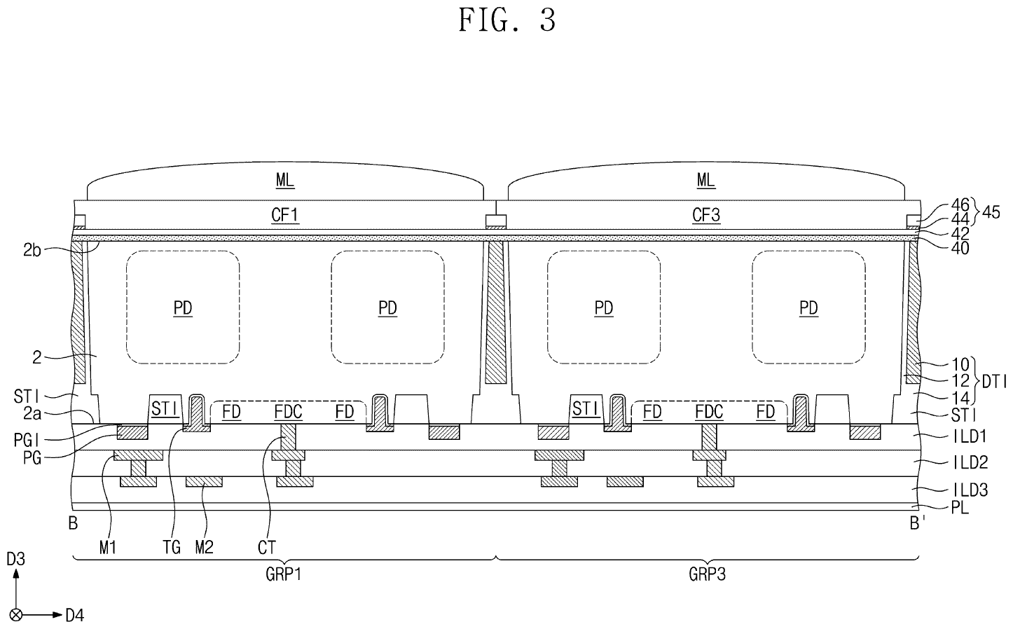

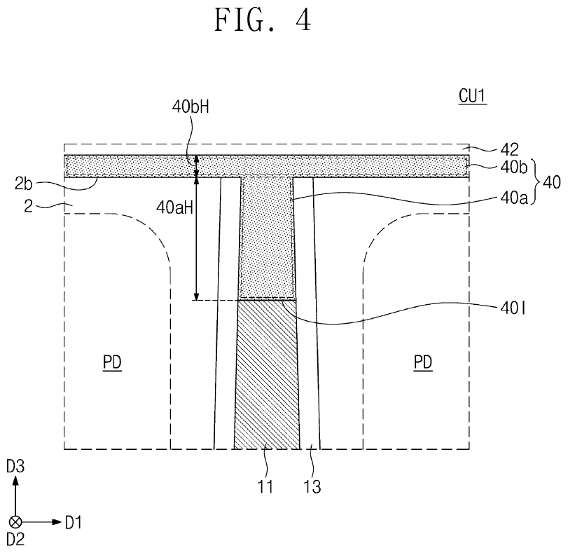

FIG. 1 is a plan view illustrating an image sensor according to some implementations of the present disclosure. FIG. 2 is a sectional view taken along a line A-A′ of FIG. 1. FIG. 3 is a sectional view taken along a line B-B′ of FIG. 2. FIG. 4 is an enlarged sectional view illustrating a portion ‘CU1’ of FIG. 2.

Referring to FIGS. 1 to 4, an image sensor may include a substrate 2. The substrate 2 may include a first surface 2a and a second surface 2b, which are opposite to each other. Light may be incident into the substrate 2 through the second surface 2b. The substrate 2 may be a single crystalline wafer, which is formed of or includes silicon and/or germanium, an epitaxial layer, or a silicon-on-insulator (SOI) wafer, to provide several non-limiting examples. Other types of substrates are also within the scope of this disclosure.

The substrate 2 may include a first active region ACT1 and a second active region ACT2, which are defined by a device isolation portion STI to be described below. The first active region ACT1 may be disposed to enclose the second active region ACT2.

In the present specification, a first direction D1 may be defined as a direction parallel to the first surface 2a of the substrate 2. A second direction D2 may be defined as a direction, which is parallel to the first surface 2a of the substrate 2 and is perpendicular to the first direction D1. A third direction D3 may be perpendicular to the first surface 2a of the substrate 2. A fourth direction D4 may be defined as a direction that is parallel to the first surface 2a of the substrate 2 and is not parallel to the first and second directions D1 and D2.

In some implementations, an image sensor 1 includes first to fourth pixel groups GRP1 to GRP4, which are disposed on the substrate 2 in a clockwise direction. The first and second pixel groups GRP1 and GRP2 may be adjacent to each other in the first direction D1. The second and third pixel groups GRP2 and GRP3 may be adjacent to each other in the second direction D2. The third and fourth pixel groups GRP3 and GRP4 may be adjacent to each other in the first direction D1. The first and fourth pixel groups GRP1 and GRP4 may be adjacent to each other in the second direction D2. The first to fourth pixel groups GRP1 to GRP4 may be separated from each other in a first isolation structure DTI, which will be described below.

Each of the first to fourth pixel groups GRP1 to GRP4 may include a plurality of pixel regions PX and photoelectric conversion parts (or portions, or regions) PD in the pixel regions PX. The photoelectric conversion parts PD may be separated from each other by a second isolation structure CDTI, which will be described below.

In at least one of the pixel regions PX, a pixel gate electrode PG may be disposed in a first interlayer insulating layer ILD1 to be described below. The pixel gate electrode PG, in conjunction with source/drain regions in the first active region ACT1, may constitute a pixel transistor. In some implementations, the pixel transistor may be one of a reset transistor, a source follower transistor, a double conversion gain transistor, or a selection transistor.

In at least one of the pixel regions PX, the pixel gate electrode PG may not be disposed in the first interlayer insulating layer ILD1. Alternatively, or in addition, a ground region GND may be disposed on at least one of the pixel regions PX. The arrangement of the pixel gate electrode PG and the ground region GND may be variously combined or changed.

Each of the pixel regions PX may include a transfer gate electrode TG, which is disposed on the second active regions ACT2, and floating diffusion regions FD. A common floating diffusion region FDC may be disposed at a center of the first to fourth pixel groups GRP1 to GRP4. The common floating diffusion region FDC may be electrically connected to the floating diffusion regions FD in each of pixel groups GRP1 to GRP4.

Referring back to FIGS. 2 and 3, the substrate 2 may be doped with first impurities to have a first conductivity type. The first impurities may be, for example, boron. The first conductivity type may be, for example, p-type.

The first isolation structure DTI may be disposed in the substrate 2 to separate the first to fourth pixel groups GRP1 to GRP4 from each other. The first isolation structure DTI may be provided to penetrate or extend through the substrate 2. A width of the first isolation structure DTI may decrease as it transitions from the first surface 2a to the second surface 2b.

The first isolation structure DTI may include a first isolation conductive pattern 10, a first isolation insulating pattern 12, and a first gapfill insulating pattern 14. The first isolation conductive pattern 10 may be disposed to be spaced apart from the substrate 2. The first isolation conductive pattern 10 may include a conductive material having a refractive index different from the substrate 2. In some implementations, the first isolation conductive pattern 10 includes at least one of doped polysilicon or metallic material(s).

The first isolation insulating pattern 12 may be interposed between the first isolation conductive pattern 10 and the substrate 2. The first gapfill insulating pattern 14 may be disposed below the first isolation conductive pattern 10. The first isolation insulating pattern 12 and the first gapfill insulating pattern 14 may include an insulating material having a different refractive index from the substrate 2. In some implementations, the first isolation insulating pattern 12 and the first gapfill insulating pattern 14 are formed of or include silicon oxide.

A second isolation structure CDTI may be disposed in the substrate 2 to separate the photoelectric conversion parts PD, which are included in the first to fourth pixel groups GRP1 to GRP4, from each other. The second isolation structure CDTI may be spaced apart from the first isolation structure DTI in the first and second directions D1 and D2. In some implementations, a plurality of second isolation structures CDTI are provided in the first and second directions D1 and D2. The second isolation structure CDTI may be provided to penetrate or extend through the substrate 2. A width of the second isolation structure CDTI may decrease as it transitions from the first surface 2a to the second surface 2b.

The second isolation structure CDTI may include a second isolation conductive pattern 11, a second isolation insulating pattern 13, and a second gapfill insulating pattern 15. The second isolation conductive pattern 11 may be disposed to be spaced apart from the substrate 2. The second isolation conductive pattern 11 may include a conductive material having a refractive index different from the substrate 2. The second isolation conductive pattern 11 may include doped polysilicon or metallic material(s).

Here, a height 11H (e.g., thickness in the third direction D3) of the second isolation conductive pattern 11 may be smaller than a height 10H (e.g., thickness in the third direction D3) of the first isolation conductive pattern 10. In some implementations, the height 11H of the second isolation conductive pattern 11 is 60% to 70% of a thickness of the substrate 2.

The second isolation insulating pattern 13 may be interposed between the second isolation conductive pattern 11 and the substrate 2 and between the substrate 2 and an oxide structure 40 to be described below. The second gapfill insulating pattern 15 may be disposed below the second isolation conductive pattern 11. The second isolation insulating pattern 13 and the second gapfill insulating pattern 15 may include an insulating material having a different refractive index from the substrate 2. As an example, the second isolation insulating pattern 13 and the second gapfill insulating pattern 15 may be formed of or include silicon oxide.

A negative bias voltage may be applied to the first and second isolation conductive patterns 10 and 11. The first and second isolation conductive patterns 10 and 11 may serve as a common bias line. Thus, it may be possible to hold holes, which may be present on a surface of the substrate 2 in contact with the first and second isolation structures DTI and CDTI, and thereby to improve a dark current property of the image sensor.

An oxide structure 40 may be disposed on the second isolation conductive pattern 11 of the second isolation structure CDTI. An upper portion of the second isolation insulating pattern 13 may be provided to enclose (e.g., laterally enclose) a side (or lateral) surface of the oxide structure 40. Here, as shown in FIG. 4, a bottom surface of the oxide structure 40 may be placed between the first and second surfaces 2a and 2b of the substrate 2, such that the oxide structure is at least partially embedded in the substrate 2. That is, a level 40l of the bottom surface of the oxide structure 40 may be lower than the second surface 2b. For example, the oxide structure can protrude into the substrate from the second surface 2b of the substrate 2.

In some implementations, as shown in FIG. 4, the oxide structure 40 includes a first portion 40a and a second portion 40b on the first portion 40a. The first portion 40a may have a shape protruding from the second portion 40b. The second portion 40b may be extended, on the second surface 2b. The first and second portions 40a and 40b may be connected to form a single object.

The first portion 40a may be in contact with the second isolation conductive pattern 11. The second isolation insulating pattern 13 may enclose a side (or lateral) surface of the first portion 40a. A level of a bottom surface of the first portion 40a may be lower than a level of a top surface of the first isolation structure DTI. A height 40aH of the first portion 40a may be larger than a height 40bH of the second portion 40b. In the present specification, the height 40aH of the first portion 40a and the height 40bH of the second portion 40b correspond to a thickness of the first portion 40a and a thickness of the second portion 40b, respectively.

The height 40aH of the first portion 40a may be 20% to 30% of a thickness of the substrate 2. In some implementations, the height 40aH of the first portion 40a is in a range from 0.5μm to 1.5 μm. In some implementations, because the height 40aH of the first portion 40a is less than 30% of the thickness of the substrate 2, the dark current improvement, which is achieved by the second isolation conductive pattern 11, may not be interfered with by the first portion 40a.

The second portion 40b may be in contact with the second surface 2b of the substrate 2 and the top surface of the first isolation structure DTI. For example, the second portion 40b may be in contact with the first isolation conductive pattern 10 in the first isolation structure DTI.

The oxide structure 40 may include a metal oxide. In some implementations, the oxide structure 40 includes at least one of aluminum oxide or hafnium oxide.

A device isolation portion STI may be disposed on the first surface 2a of the substrate 2. The first and second isolation structures DTI and CDTI may be provided on the device isolation portion STI. In some implementations, the device isolation portion STI and portions of the first and second isolation structures DTI and CDTI (e.g., the first isolation insulating pattern 12, the first gapfill insulating pattern 14, the second isolation insulating pattern 13, and/or the second gapfill insulating pattern 15) are formed of the same material. In some implementations, when the device isolation portion STI and portions of the first and second isolation structures DTI and CDTI are formed of the same material, a content of the material in the device isolation portion STI is different from that in the first and second isolation structures DTI and CDTI. For example, the content of the material may refer to the content of silicon oxide contained in the device isolation portion STI and the first and second isolation structures DTI and CDTI.

The photoelectric conversion part PD may be disposed in the substrate 2. A well region PW may be disposed between the photoelectric conversion part PD and the first surface 2a. In some implementations, the well region PW is doped with the first impurities to have a first conductivity type. The first impurities may be, for example, boron. The first conductivity type may be, for example, p-type. A concentration of the first impurity doped in the well region PW may be equal to or greater than a concentration of the impurity doped in the substrate 2.

The photoelectric conversion part PD may be doped with second impurities, which are different from the first impurities, to have a second conductivity type. The second impurity may be, for example, phosphorus or arsenic. The second conductivity type may be, for example, n-type. The photoelectric conversion part PD of the n-type region, in conjunction with a neighboring region of the substrate 2 and/or the well region PW of the p-type region, may form a PN junction, which is used as a photodiode, and if light is incident to the PN junction, electron-hole pairs may be generated from the PN junction.

The pixel gate electrode PG may be provided on the first surface 2a of the substrate 2. The pixel gate electrode PG may be formed of or include at least one of doped polysilicon, conductive metal nitride, conductive metal silicide, conductive metal oxide, or combinations thereof. A gate insulating layer PGI may be interposed between the pixel gate electrode PG and the substrate 2.

The common floating diffusion region FDC may be provided on the first surface 2a of the substrate 2, as shown in FIG. 3. The floating diffusion region FD may be a portion of the common floating diffusion region FDC. The pixel regions PX in each of the pixel groups GRP1 to GRP4 may be electrically connected to each other through the common floating diffusion region FDC.

In some implementations, the first isolation structure DTI is disposed on the common floating diffusion region FDC to extend from the second surface 2b toward the first surface 2a. In at least this case, the first isolation structure DTI may be spaced apart from the common floating diffusion region FDC.

The transfer gate electrode TG may be provided on the first surface 2a. The transfer gate electrode TG may include a protruding portion, which is inserted into the substrate 2. An insulating layer may be interposed between the transfer gate electrode TG and the substrate 2.

First to third interlayer insulating layers ILD1, ILD2, and ILD3 and a passivation layer PL may be sequentially formed on the first surface 2a of the substrate 2. In some implementations, each of the first to third interlayer insulating layers ILD1, ILD2, and ILD3 is formed of or includes at least one of silicon oxide, silicon nitride, or silicon oxynitride. The passivation layer PL may be formed of or include, for example, silicon nitride.

A connection contact CT may be provided to penetrate or extend through the first interlayer insulating layer ILD1. The connection contact CT may be connected to the common floating diffusion region FDC. First metal lines M1 and second metal lines M2 may be provided in the second interlayer insulating layer ILD2 and the third interlayer insulating layer ILD3, respectively. The connection contact CT, the first metal lines M1, and the second metal lines M2 may be formed of or include at least one conductive material (e.g., metallic materials).

An anti-reflection layer 42 may be disposed on the oxide structure 40. The anti-reflection layer 42 may be in contact with the second portion 40b of the oxide structure 40. In some implementations, the anti-reflection layer 42 is formed of or includes silicon nitride.

A grid 45 may be provided on the first isolation structure DTI and the anti-reflection layer 42. The grid 45 may include a first pattern 44 and a second pattern 46. The first pattern 44 may be an optically opaque material (e.g., titanium). A side surface of the second pattern 46 may be aligned to a side surface of the first pattern 44. The first and second patterns 44 and 46 may prevent a cross-talk issue from occurring between adjacent ones of the pixels. The second pattern 46 may include an organic material. The second pattern 46 may have a refractive index of about 1.3 or lower.

Color filters CF1 to CF3 may be disposed on the anti-reflection layer 42. The color filters CF1 to 3 may include a photoresist material containing dye or pigment. Here, the color filters CF1 to CF3, which are respectively disposed in different ones of the pixel groups GRP1 to GRP4, may have different colors from each other and may be arranged to form a Bayer pattern.

In some implementations, color filters of the same color are disposed on the pixel groups GRP1 to GRP4. Here, a color filter of a different color may be disposed on another pixel group, which includes 16 pixel regions PX adjacent to each other. In this case, the color filters may form a 32 ×32 Bayer pattern on the photoelectric conversion parts PD. It will be understood that various combinations of color filters and corresponding colors, and patterns thereof, are within the scope of this disclosure.

A micro lens ML may be disposed on the color filters CF1-CF3. The second isolation structure CDTI may overlap with the micro lens ML along the third direction D3. When measured from a center region of the micro lens ML, the first isolation structure DTI may be farther (e.g., laterally farther, parallel to the surfaces 2a, 2b) from the center region of the micro lens ML than the second isolation structure CDTI.

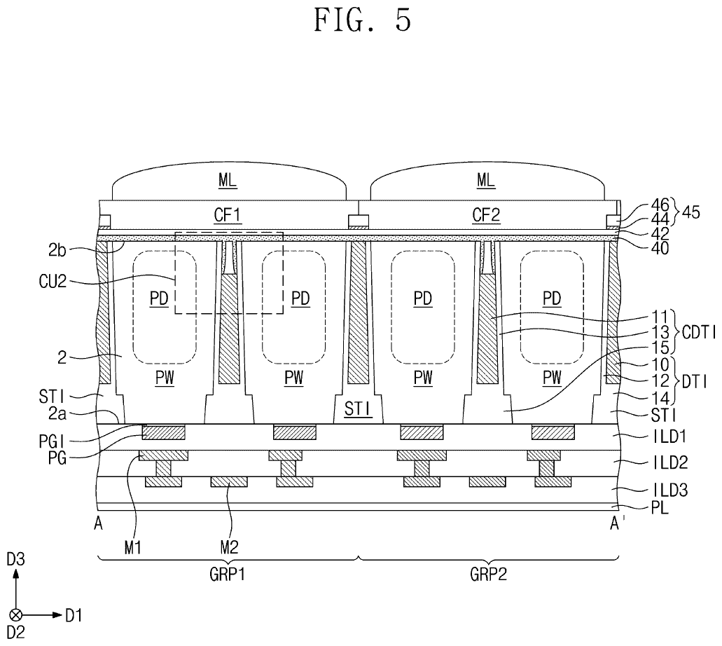

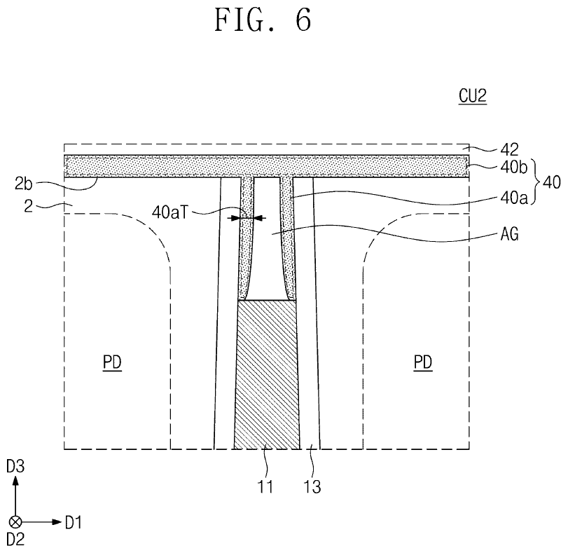

FIG. 5 is a sectional view taken along the line A-A′ of FIG. 1. FIG. 6 is an enlarged sectional view illustrating a portion ‘CU2’ of FIG. 5. An element previously described with reference to FIGS. 2 to 4 may be identified by the same reference number without repeating an overlapping description thereof.

Referring to FIGS. 5 and 6, an air gap AG may be interposed between the second isolation conductive pattern 11 and the oxide structure 40. When viewed in a horizontal or cross-sectional view, the first portion 40a of the oxide structure 40 may be placed between the air gap AG and the second isolation insulating pattern 13, e.g., along the first direction D1 and/or the second direction D2. When viewed in a vertical section or cross-sectional view, the air gap AG may be placed between the second isolation conductive pattern 11 and the second portion 40b of the oxide structure 40, e.g., along the third direction D3. A thickness 40aT of the first portion 40a of the oxide structure 40 in the first direction D1 may range from 8 nm to 12 nm. Due to the presence of the air gap AG, light passing through the micro lens ML may not be refracted, and this may make it possible to increase an amount of light incident into the photoelectric conversion part PD.

Accordingly, an image sensor may include a micro lens and an isolation structure, which is vertically overlapped with the micro lens and includes a conductive pattern. Here, an oxide structure (e.g., oxide structures 40 of FIGS. 1-6 and 11) may be provided on the conductive pattern of the isolation structure. Thus, due to the total reflection by the oxide structure, light, which is incident through the micro lens, may enter a photoelectric conversion part in a substrate. This may make it possible to increase an amount of light incident to the photoelectric conversion part, and thus, the image sensor may have an improved sensitivity and an improved optical property. In some implementations, a material of the oxide structure (e.g., hafnium oxide or aluminum oxide) may advantageously promote total internal reflection, e.g., compared to other materials such as polysilicon or silicon oxide. For example, favorable optical behavior may be based on the oxide structure's absorption and/or refractive index.

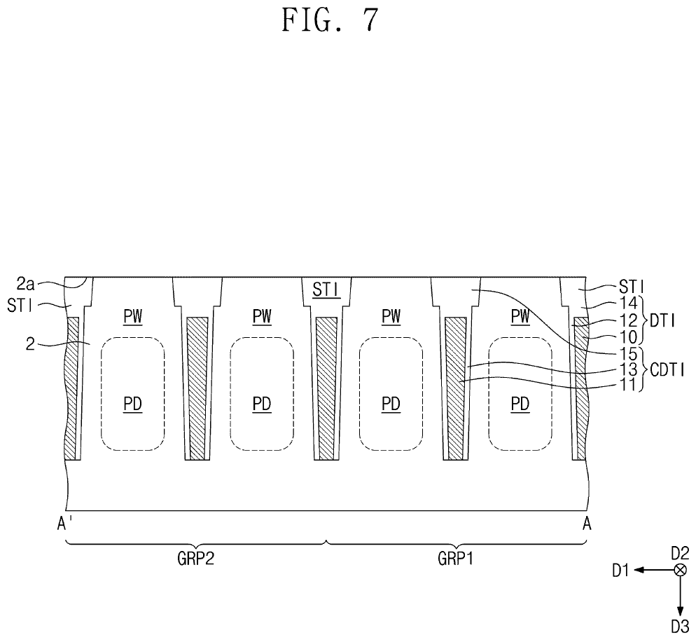

FIGS. 7, 8, 9, and 10 are sectional views illustrating a process of fabricating an image sensor according to some implementations of the present disclosure.

Referring to FIGS. 1 and 7, the substrate 2 having the first and second surfaces 2a and 2b, which are opposite to each other, may be provided. The substrate 100 may have a first conductivity type (e.g., p-type). The device isolation portion STI may be formed on the first surface 2a of the substrate 2. The device isolation portion STI may be formed to define the first active region ACT1 and the second active region ACT2. In some implementations, the device isolation portion STI is formed through a shallow trench isolation (STI) process.

The first and second isolation structures DTI and CDTI may be formed on the device isolation portion STI. The pixel groups GRP1 to GRP4 may be separated from each other by the first isolation structure DTI. The photoelectric conversion parts PD in the pixel groups GRP1 to GRP4 may be separated from each other by the second isolation structure CDTI.

The first isolation structure DTI may include the first isolation conductive pattern 10, the first isolation insulating pattern 12, and the first gapfill insulating pattern 14. The second isolation structure CDTI may include the second isolation conductive pattern 11, the second isolation insulating pattern 13, and the second gapfill insulating pattern 15.

The well region PW and the photoelectric conversion part PD may be formed in the substrate 2. The formation of the well region PW may include injecting first impurities into the substrate 2. The formation of the photoelectric conversion part PD may include injecting second impurities, which are different from the first impurities, into the substrate 2.

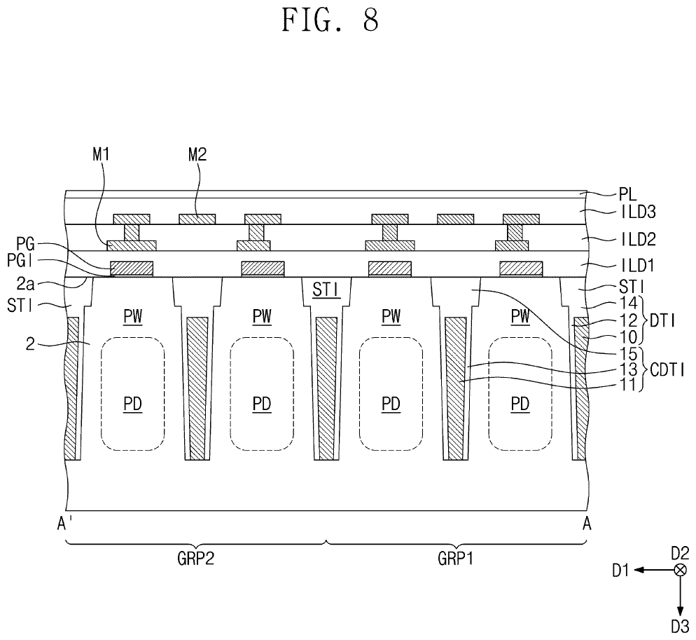

Referring to FIG. 8, the gate insulating layer PGI and the pixel gate electrode PG may be formed on the first surface 2a of the substrate 2. Thereafter, first to third interlayer insulating layers ILD1 to ILD3 and the passivation layer PL may be sequentially formed on the first surface 2a of the substrate 2. Here, first metal lines ML1 and second metal lines ML2 may be respectively formed in the second interlayer insulating layer ILD2 and the third interlayer insulating layer ILD3.

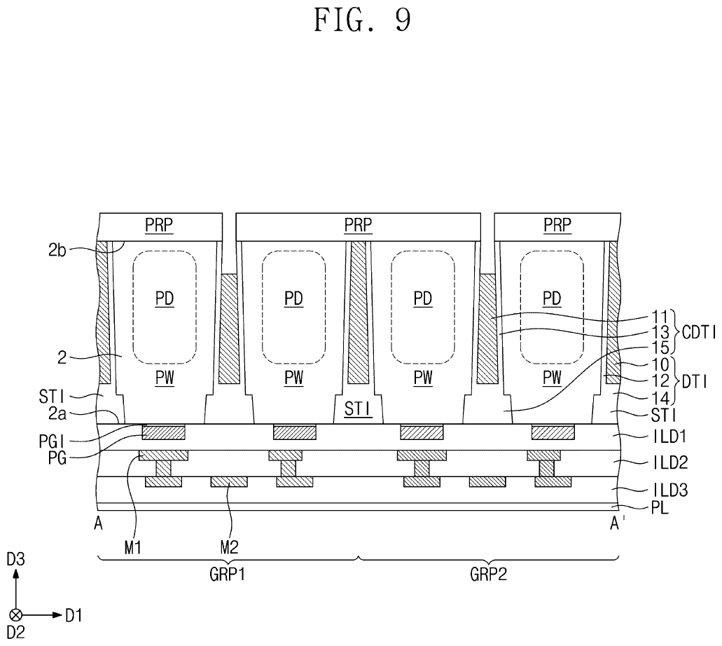

Referring to FIGS. 4 and 9, the substrate 2, the first to third interlayer insulating layers ILD1 to ILD3, and the passivation layer PL of FIG. 8 may be inverted. A grinding process may be performed on the second surface 2b of the substrate 2 to expose top surfaces of the first and second isolation structures DTI and CDTI. As a result of the grinding process, a thickness of the substrate 2 in the third direction D3 may be reduced.

A photoresist pattern PRP may be formed on the second surface 2b. The photoresist pattern PRP may expose a top surface of the second isolation conductive pattern 11. The photoresist pattern PRP may define a region, on which the first portion 40a of the oxide structure 40 will be formed.

Next, an etching process may be performed to remove a portion of the second isolation conductive pattern 11. As a result of the partial removal of the second isolation conductive pattern 11, the height of the second isolation conductive pattern 11 may be reduced. In some implementations, the removal depth of the second isolation conductive pattern 11 is in a range from 0.5 μm to 1.5 μm. Thereafter, the photoresist pattern PRP may be removed.

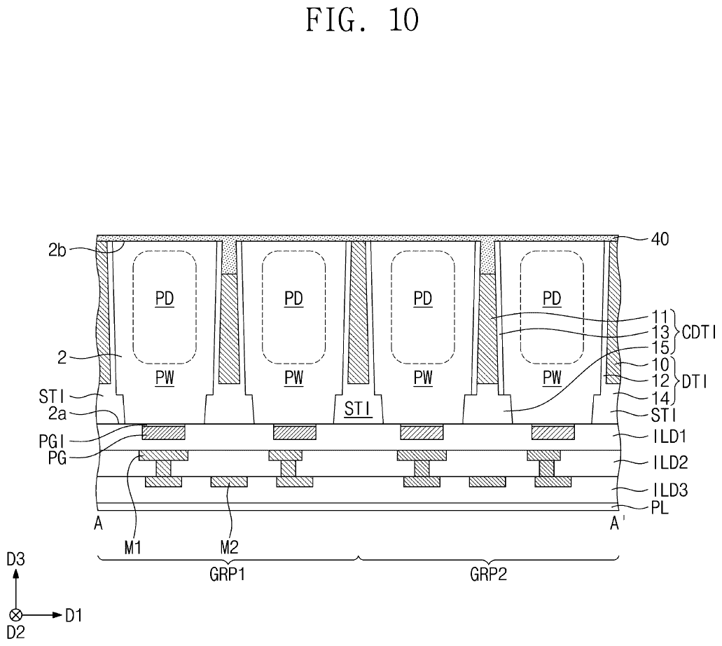

Referring to FIG. 10, the oxide structure 40 may be formed on the second surface 2b of the substrate 2. Here, the oxide structure 40 may fill a region, which is formed by partially removing the second isolation conductive pattern 11. In some implementations, the oxide structure 40 is formed by a plasma-enhanced chemical vapor deposition (PECVD) process.

Next, referring back to FIG. 2, the anti-reflection layer 42 may be formed on the oxide structure 40. The first and second patterns 44 and 46 may be sequentially formed on the anti-reflection layer 42. The color filter CF1-CF3 may be formed on the anti-reflection layer 42. Next, the micro lens ML may be formed on the color filter CF1-CF3, and an image sensor as described herein may be fabricated.

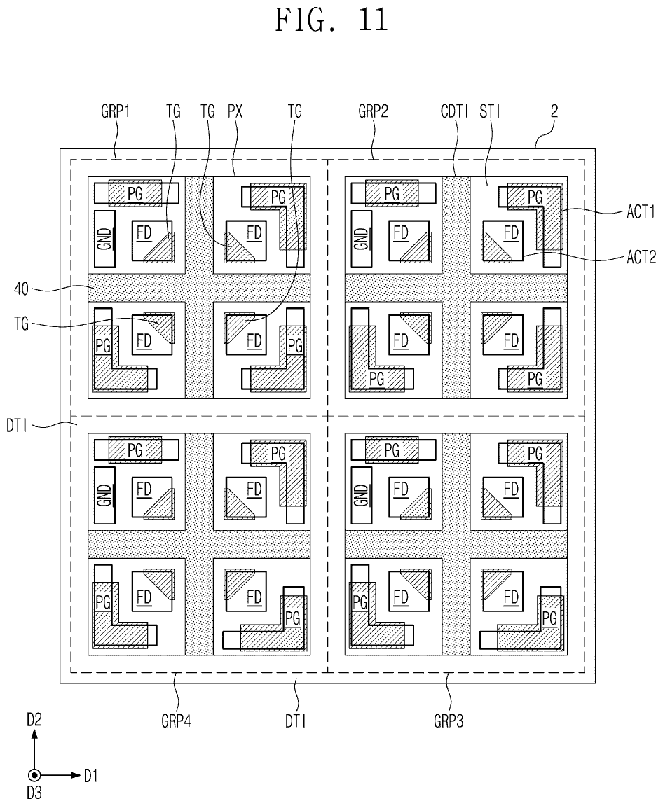

FIG. 11 is a plan view illustrating an image sensor according to some implementations. For concise description, an element previously described with reference to FIG. 1 may be identified by the same reference number without repeating an overlapping description thereof.

Referring to FIG. 11, each of the pixel groups GRP1 to GRP4 may not include a common floating diffusion region in a center region thereof. That is, the second isolation structure CDTI may be placed in the center region of each of the pixel groups GRP1 to GRP4, when viewed in a plan view. Since the common floating diffusion region is not provided, the pixel regions PX in each of the pixel groups GRP1 to GRP4 may be independently controlled, and signals generated by the incident light may be separately processed.

Accordingly, an image sensor may include a micro lens and an isolation structure, which is vertically overlapped with the micro lens and includes a conductive pattern. An oxide structure may be provided on the conductive pattern of the isolation structure. Thus, due to the total reflection by the oxide structure, light, which is incident through the micro lens, may enter a photoelectric conversion part in a substrate. This may make it possible to increase an amount of light incident to the photoelectric conversion part, and thus, the image sensor may have an improved sensitivity and an improved optical property.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While various examples have been particularly shown and described, it will be understood by one of ordinary skill in the art that variations in form and detail may be made therein without departing from the spirit and scope of the present disclosure.

What is claimed is:

1. An image sensor, comprising:
a substrate having a first surface and a second surface opposite to one another, wherein the substrate comprises a first photoelectric conversion region and a second photoelectric conversion region;
a first isolation structure arranged in the substrate between the first photoelectric conversion region and the second photoelectric conversion region;
an oxide structure on the first isolation structure; and
a micro lens on the oxide structure,
wherein the first isolation structure and the micro lens overlap along a vertical direction,
wherein the first isolation structure comprises a first isolation conductive pattern,
wherein the oxide structure is in contact with the first isolation conductive pattern, and
wherein the oxide structure is at least partially extended into the first isolation structure.

2. The image sensor of claim 1, wherein the oxide structure comprises at least one of hafnium oxide or aluminum oxide, and
wherein the first isolation conductive pattern comprises doped polysilicon.

3. The image sensor of claim 1, further comprising a second isolation structure in the substrate and spaced apart from the first isolation structure in a first direction parallel to the first surface,
wherein the second isolation structure comprises a second isolation conductive pattern, and
wherein a thickness of the first isolation conductive pattern in the vertical direction is smaller than a thickness of the second isolation conductive pattern in the vertical direction.

4. The image sensor of claim 3, wherein a top surface of the second isolation conductive pattern is higher along the vertical direction than a top surface of the first isolation conductive pattern, and
wherein the top surface of the second isolation conductive pattern is in contact with the oxide structure.

5. The image sensor of claim 3, wherein a thickness of the first isolation conductive pattern in the vertical direction is 60% to 70% of a thickness of the substrate.

6. The image sensor of claim 3, further comprising a portion of an opaque grid overlapping with the second isolation structure along the vertical direction.

7. The image sensor of claim 1, wherein the first isolation structure comprises an isolation insulating pattern interposed between the substrate and the first isolation conductive pattern, and
wherein an upper portion of the isolation insulating pattern is arranged to laterally enclose the oxide structure.

8. The image sensor of claim 1, wherein a width of the first isolation conductive pattern decreases as a distance to the micro lens decreases.

9. An image sensor, comprising:
a substrate having a first surface and a second surface opposite to one another, wherein the substrate comprises a plurality of photoelectric conversion regions;
a first isolation structure and a second isolation structure in the substrate and spaced apart from each other in a first direction parallel to the first surface;
an oxide structure on the first isolation structure; and
a micro lens on the oxide structure,
wherein the first isolation structure is overlapping with the micro lens along a vertical direction,
wherein the first isolation structure comprises a first isolation conductive pattern,
wherein the oxide structure comprises a first portion and a second portion on the first portion,
wherein the first portion is in contact with the first isolation conductive pattern,
wherein the second portion extends on the second surface of the substrate, and
wherein a thickness of the first portion in the vertical direction is larger than a thickness of the second portion in the vertical direction.

10. The image sensor of claim 9, wherein the thickness of the first portion of the oxide structure in the vertical direction is in a range from 0.5 μm to 1.5 μm.

11. The image sensor of claim 9, wherein the second portion is in contact with the second surface of the substrate and a top surface of the second isolation structure.

12. The image sensor of claim 9, wherein the thickness of the first portion in the vertical direction is in a range from 20% to 30% of a thickness of the substrate.

13. The image sensor of claim 9, wherein the first isolation structure comprises an isolation insulating pattern interposed between the substrate and the first isolation conductive pattern, and
wherein the isolation insulating pattern is arranged to enclose a lateral surface of the first portion of the oxide structure.

14. The image sensor of claim 13, further comprising an air gap between the first isolation conductive pattern and the oxide structure along the vertical direction,
wherein the first portion of the oxide structure is arranged between the air gap and the isolation insulating pattern along the first direction.

15. The image sensor of claim 14, wherein a thickness of the oxide structure in the first direction is in a range from 8 nm to 12 nm.

16. An image sensor, comprising:
a substrate including a first pixel group and a second pixel group adjacent to one another, each of the first and second pixel groups comprising a plurality of photoelectric conversion regions,
a first isolation structure in the substrate between the first pixel group and the second pixel group;
a second isolation structure in the substrate between a first photoelectric conversion region of the first pixel group and a second photoelectric conversion region of the first pixel group, and between a first photoelectric conversion region of the second pixel group and a second photoelectric conversion region of the second pixel group; and
an oxide structure on the second isolation structure,
wherein the first isolation structure comprises a first isolation conductive pattern and the second isolation structure comprises a second isolation conductive pattern,
wherein a thickness of the second isolation conductive pattern in a vertical direction is smaller than a thickness of the first isolation conductive pattern in the vertical direction,
wherein the oxide structure comprises a first portion and a second portion protruding from the first portion,
wherein the first portion is in contact with the first isolation conductive pattern,
wherein the second portion is in contact with the second isolation conductive pattern, and
wherein a thickness of the second portion in the vertical direction is in a range from 0.5μm to 1.5 μm.

17. The image sensor of claim 16, wherein the first isolation conductive pattern and the second isolation conductive pattern are configured as a common bias line.

18. The image sensor of claim 16, wherein a bottom surface of the second portion of the oxide structure is lower than a top surface of the first isolation structure.

19. The image sensor of claim 16, further comprising:
an anti-reflection layer on the oxide structure;
a color filter on the anti-reflection layer; and
a micro lens on the color filter.

20. The image sensor of claim 19, wherein a lateral distance between the first isolation structure and a center of the micro lens is larger than a lateral distance between the second isolation structure and the center of the micro lens.
